(19) United States
(12) Patent Application Publication
(10) Pub. No.: US 2012/0175503 A1
(43) Pub. Date: Jul. 12, 2012

(54) PHOTOELECTRIC CONVERSION APPARATUS

(75) Inventors: Yukihiro Kuroda, Kunitachi-shi (JP); Hideo Kobayashi, Tokyo (JP)

(73) Assignee: CANON KABUSHIKI KAISHA, Tokyo (JP)

(21) Appl. No.: 13/326,898

(22) Filed: Dec. 15, 2011

(30) Foreign Application Priority Data
Jan. 11, 2011 (JP) 2011-003112

(51) Int. Cl. H01L 31/02

(52) U.S. Cl. 250/214 A

(57) ABSTRACT

There is provided a photoelectric conversion apparatus capable of obtaining good photoelectric conversion characteristics regardless of a decrease in current amplification ratio of the phototransistor and manufacturing variations in phototransistor. The photoelectric conversion apparatus includes a photoelectric conversion element that generates a current by photoelectric conversion; a transistor that inputs a current generated by the photoelectric conversion element to a base thereof, amplifies the input current, and outputs the amplified current from an emitter; a logarithmic conversion unit that logarithmically converts the current output from the transistor; a current generating unit that outputs the current to the base of the transistor; and a current controlling unit that controls the output current of the current generating unit in a light shielding state of the photoelectric conversion element based on the signal logarithmically converted by the logarithmic conversion unit.

### BACKGROUND OF THE INVENTION

1. Field of the Invention

The present invention relates to a photoelectric conversion apparatus.

2. Description of the Related Art

There has conventionally been disclosed a photoelectric conversion apparatus that receives light in the base of a phototransistor and outputs an amplified photocurrent from the emitter (for example, see Japanese Patent Application Laid-Open No. 2000-077644). In the case of low-light intensity, the phototransistor generates a slight base current. Accordingly, the recombination current component between the base and the emitter of the phototransistor is the main component of the current, thus causing insufficient carrier injection from the emitter to the collector. As a result, the current amplification ratio decreases and the photoelectric conversion characteristics at low-light intensity degrade. In order to solve this problem, there has been disclosed a photoelectric conversion apparatus that injects a carrier by flowing a current through the base (for example, see Japanese Patent Application Laid-Open No. H08-264744).

Unfortunately, Japanese Patent Application Laid-Open No. H08-264744 does not disclose a means of determining the value of the current to flow through the base, and hence has a problem in that an appropriate carrier cannot be injected when the current amplification ratio of the phototransistor decreases. In addition, Japanese Patent Application Laid-Open No. H08-264744 has another problem in that an appropriate carrier cannot be injected into an individual phototransistor greatly affected by manufacturing variations due to pixel multiplication and microminiaturization of the phototransistor.

It is an object of the present invention to provide a photoelectric conversion apparatus capable of obtaining good photoelectric conversion characteristics regardless of a decrease in current amplification ratio of the phototransistor and manufacturing variations in phototransistor.

### SUMMARY OF THE INVENTION

According to an aspect of the present invention, a photoelectric conversion apparatus comprises: a photoelectric conversion element for generating a current by a photoelectric conversion; a transistor having a base inputted the current generated by the photoelectric conversion element, amplifying the input current and outputting the amplified current from an emitter thereof; a logarithmic conversion unit for logarithmically converting the current output from the transistor; a current generating unit for inputting a current to the base of the transistor; and a current controlling unit for the current output from the current generating unit, based on the signal converted logarithmically by the logarithmic conversion unit under a light shielding state of the photoelectric conversion element.

Further features of the present invention will become apparent from the following description of exemplary embodiments with reference to the attached drawings.

### BRIEF DESCRIPTION OF THE DRAWINGS

FIG. 1 is a schematic configuration view of a photoelectric conversion apparatus according to a first embodiment of the present invention.

FIG. 2 is an explanatory drawing of a current controlling unit according to the first embodiment of the present invention.

FIG. 3 is an explanatory drawing describing that the current amplification ratio of a phototransistor has a base current dependency.

FIG. 4 is a photoelectric conversion characteristic drawing according to the first embodiment of the present invention.

FIG. 5 is a detailed drawing of a current generating unit according to a second embodiment of the present invention.

FIG. 6 is a detailed drawing of a current generating unit according to a third embodiment of the present invention.

FIG. 7 is a detailed drawing of a current generating unit according to a fourth embodiment of the present invention.

### DESCRIPTION OF THE EMBODIMENTS

Preferred embodiments of the present invention will now be described in detail in accordance with the accompanying drawings.

The present invention will be described referring to specific embodiments. In the present description, a transistor whose base is connected to a photoelectric conversion element is referred to as a phototransistor. Note that the term simply means that its base is connected to a photoelectric conversion element and should not be construed to limit the function and the like in any way. In particular, the semiconductor region forming the anode of the photoelectric conversion element may be shared by the base of the transistor.

### First Embodiment

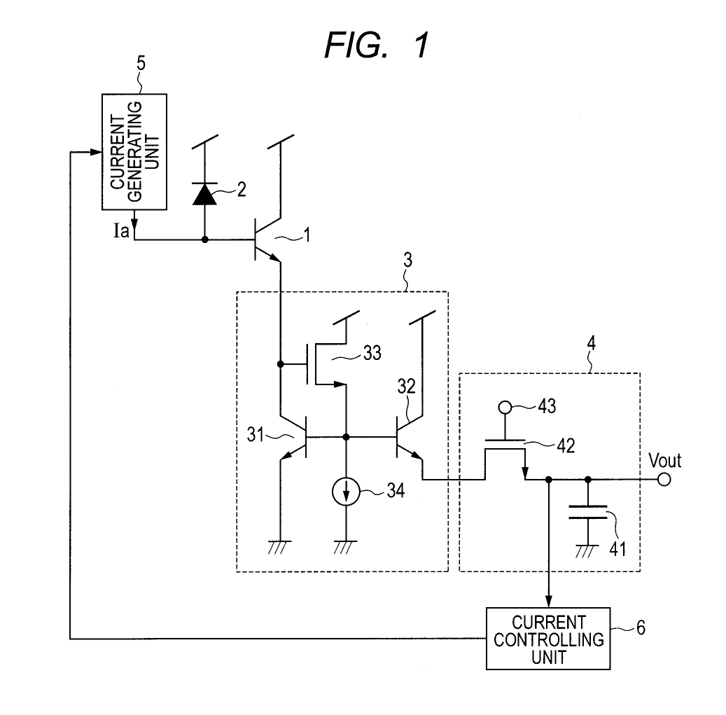

FIG. 1 is a schematic configuration view illustrating a photoelectric conversion apparatus according to a first embodiment of the present invention. FIG. 1 includes a phototransistor 1, and a photoelectric conversion element 2 (e.g., photodiode), where its cathode is connected to a power supply voltage node. The phototransistor 1 is configured such that its base is connected to the anode of the photoelectric conversion element 2 and its collector is connected to the power supply voltage node. The photoelectric conversion element 2 converts light to an electrical signal by photoelectric conversion to generate a current (photocurrent). The phototransistor 1 inputs from the base thereof the current generated by the photoelectric conversion element 2, amplifies the input current, and outputs the amplified current from the emitter. FIG. 1 further includes a logarithmic conversion unit 3 that includes transistors 31, 32, and 33, and a constant current source 34. The bipolar transistor 31 is configured such that its collector is connected to the emitter of the phototransistor 1, and its emitter is connected to a reference voltage node (ground potential node). The field-effect transistor 33 is configured such that its gate is connected to the emitter of the phototransistor 1, its drain is connected to the power supply voltage node, and its source is connected to the base of the bipolar transistor 31. The constant current source 34 is connected to between the base of the bipolar transistor 31 and the reference voltage node. The bipolar transistor 32 is configured such that its base is connected to the base of the bipolar transistor 31 and its collector is connected to the power supply voltage node. The logarithmic conversion unit 3 logarithmically converts and outputs the current output from the phototransistor 1. FIG. 1 further includes a signal accumulation unit 4 that includes a signal accumulating capacitor 41 and a transistor 42. The field-effect transistor 42 is configured such that its gate is connected to a terminal 43, its drain is connected to the emitter of the bipolar transistor 32, and its source is connected to a terminal Vout. The signal accumulating capacitor 41 is connected to between the terminal Vout and the reference voltage node. The signal accumulation unit 4 accumulates the signal (photocurrent) logarithmically converted by the logarithmic conversion unit 3 in the signal accumulating capacitor 41 so as to keep the photocurrent time accumulation signal that can be fetched as a voltage signal from the terminal Vout. The accumulation time can be controlled by voltage control of the terminal 43, namely, by turning on and off the transistor 42. FIG. 1 further includes a current generating unit 5 that outputs a current Ia for injecting a carrier into the base of the phototransistor 1. FIG. 1 further includes a current controlling unit 6 that controls the current Ia output from the current generating unit 5 in a light shielding state of the photoelectric conversion element 2 based on the signal accumulated in the signal accumulating capacitor 41 located in the signal accumulation unit 4. The current controlling unit 6 can control the output current Ia by monitoring the output voltage of the output terminal Vout when the photoelectric conversion apparatus performs the same accumulating operation as the light accumulating operation in the light shielding state.

FIG. 2 is a block diagram illustrating a configuration example of the current controlling unit 6. FIG. 2 includes a signal comparing unit 61 that compares a preset value with the value of a signal accumulated in the signal accumulating capacitor 41. The above preset value is, for example, an emitter voltage that allows the current amplification ratio of the phototransistor 1 preliminarily measured in the light shielding state of the photoelectric conversion element 2 to be substantially an ideal value. FIG. 2 further includes a control calculating unit 62 that performs calculation for controlling the current generating unit 5 based on the comparison results of the signal comparing unit 61. FIG. 2 further includes a control signal generating unit 63 that outputs a control signal for controlling the current generating unit 5 based on the calculation results of the control calculating unit 62.

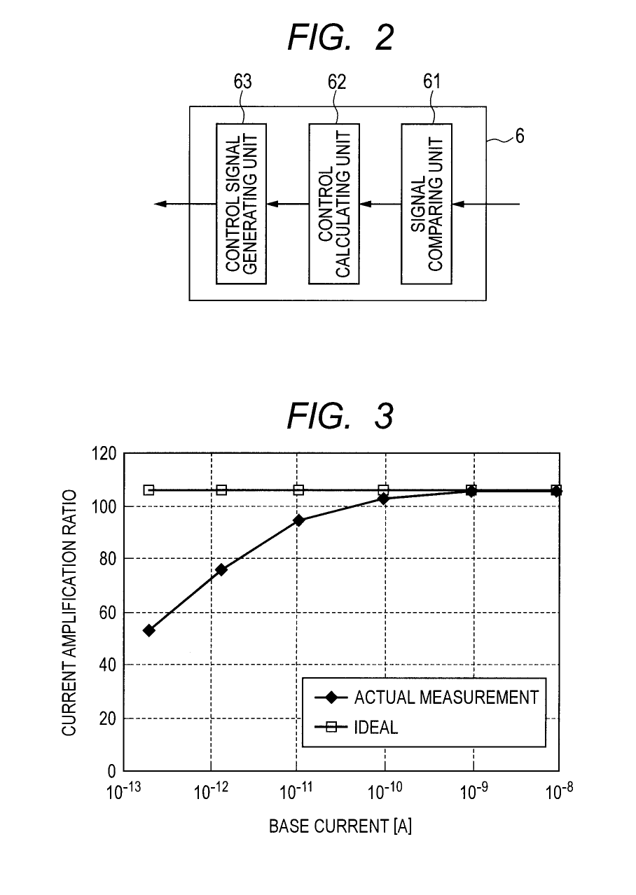

FIG. 3 is a graph illustrating a decrease in the current amplification ratio of the phototransistor 1 at low-light intensity. In FIG. 3, the horizontal axis indicates the base current of the phototransistor 1 and the vertical axis indicates the current amplification ratio of the phototransistor 1. FIG. 3 illustrates “ideal” characteristics indicating that the current amplification ratio of the phototransistor 1 does not depend on the base current of the phototransistor 1 and “actual measurements” having base current dependency. As illustrated in FIG. 3, the actual current amplification ratio decreases with a decrease in the base current. The reason for this is that when the base current decreases to minimum, the recombination current component between the base and the emitter is the main component of the current, causing insufficient injection of a carrier from the emitter to the collector. As a result, the linearity of the photoelectric conversion characteristics degrades in the low-light intensity region of the photoelectric conversion apparatus.

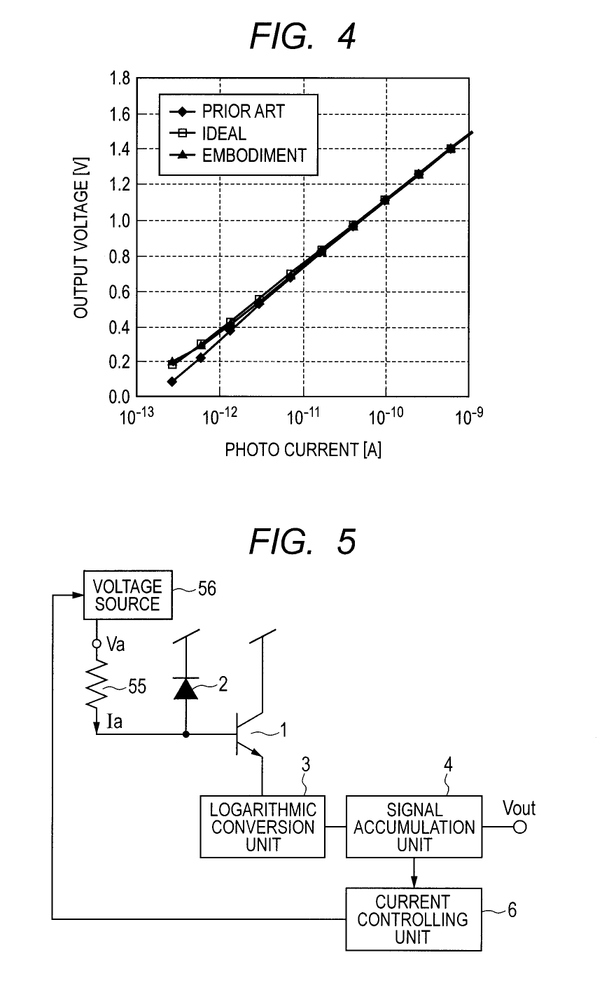

FIG. 4 is a graph illustrating an example of the photoelectric conversion characteristics of the photoelectric conversion apparatus illustrated in FIG. 1. In FIG. 4, the horizontal axis indicates the photocurrent that is equal to the base current of the phototransistor 1, and the vertical axis indicates the output voltage of the output terminal Vout. In FIG. 4, the plot indicated by “ideal” indicates that the current amplification ratio of the phototransistor 1 is ideal. In FIG. 4, the plot indicated by “prior art” is equal to the case in which no current Ia is output from the current generating unit 5 illustrated in FIG. 1. In this case, a decrease in photocurrent degrades linearity with respect to the plot indicated by “ideal”. In contrast to this, the plot indicated by “embodiment” in FIG. 4 is equal to the case in which an appropriate current Ia is output from the current generating unit 5 illustrated in FIG. 1, indicating an improvement in linearity of the photoelectric conversion characteristics in a low-light intensity region.

Thus, the linearity of the photoelectric conversion characteristics at low-light intensity is improved by outputting a current Ia for injecting a carrier into the base of the phototransistor 1 from the current generating unit 5 illustrated in FIG. 1. Further, the current Ia to be output from the current generating unit 5 can be controlled by the current controlling unit 6. For example, there can be considered a method in which an accumulation signal value at light shielding in the ideal case in which the current amplification ratio of the phototransistor 1 does not depend on the base current is preliminarily set; and then, the current generating unit 5 is controlled based on a difference voltage between the preset accumulation signal value and the output voltage of the output terminal Vout when an accumulating operation is performed in the light shielding state. The current controlling unit 6 controls the current Ia to be output from the current generating unit 5 based on the difference between a signal value accumulated in the signal accumulation unit 4 in the light shielding state of the photoelectric conversion element 2 and a signal value in the case in which the current amplification ratio of the phototransistor 1 has no base current dependency. The accumulating operation at light shielding has the same accumulation period as the accumulating operation at light incidence.

The present embodiment can use logarithmic conversion characteristics to improve the photoelectric conversion characteristics in the low-light intensity region and output an appropriate current Ia not affecting the photoelectric conversion characteristics in the light intensity region in which the current amplification ratio does not depend on the base current. As a result, the present embodiment eliminates the need to have a circuit for correcting the current component added to the phototransistor 1 at a later stage and the need to control the output current Ia during light accumulating period. Thus, the present embodiment can improve the linearity of the photoelectric conversion characteristics without complicating the circuit configuration and the system configuration.

Further, the current generating unit 5 may only output a constant current Ia during light accumulating period, and does not need to control the current Ia during the light accumulating period according to the amount of light incident on the photoelectric conversion element 2 and the accumulation time. The current generating unit 5 outputs a constant current value in a light incident state (non-light shielding state) of the photoelectric conversion element 2 during the period when the transistor 42 is turned on and a signal is written in the signal accumulation unit 4. Thus, the present embodiment can improve the linearity of the photoelectric conversion characteristics without complicating the circuit configuration and the system configuration.

The present embodiment includes the current controlling unit 6 that controls the current generating unit 5 based on a photocurrent value of the phototransistor 1. Thus, the present embodiment can inject an appropriate carrier into the base of the phototransistor 1 and obtain good photoelectric conversion characteristics regardless of a decrease in current amplification ratio of the phototransistor 1 and manufacturing variations in phototransistor.

The present embodiment has been described by taking an example of the case in which a pair of the current generating unit 5 and the current controlling unit 6 is provided for each phototransistor 1, but the present invention is not limited to this case. For example, in a case in which the photoelectric conversion apparatus includes a plurality of phototransistors, the current controlling unit 6 may be provided only in a typical phototransistor so as to control the current generating unit 5, thereby obtaining similar effects.

### Second Embodiment

FIG. 5 is a configuration example of a current generating unit 5 according to a second embodiment of the present invention. FIG. 5 illustrates an embodiment describing the current generating unit 5 in FIG. 1 further in detail. The phototransistor 1, the photoelectric conversion element 2, the logarithmic conversion unit 3, the signal accumulation unit 4, and the current controlling unit 6 in FIG. 5 are the same as those in FIG. 1. The current generating unit 5 includes a resistor element 55 and a voltage source 56. One end of the resistor element is electrically connected to the base of the photoelectric conversion element 2 and the phototransistor 1; and the other end thereof is connected to the voltage node of the voltage Va. The voltage source 56 generates the voltage Va by the control of the current controlling unit 6. Specifically, the voltage source 56 supplies the resistor element 55 with an appropriate voltage Va required to generate a current Ia to be added to the base of the phototransistor 1. Thus, from the aforementioned reason, the present embodiment can improve the linearity of the photoelectric conversion characteristics in the low-light intensity region. The present embodiment has been described by taking an example of the case in which a pair of the current controlling unit 6 and the voltage source 56 is provided for each phototransistor 1, but the present invention is not limited to this case. For example, in a case in which the photoelectric conversion apparatus includes a plurality of phototransistors, the voltage source 56 may be shared with the plurality of phototransistors and the current controlling unit 6 may be provided only in a typical phototransistor so as to control the voltage source 56, thereby obtaining similar effects.

### Third Embodiment

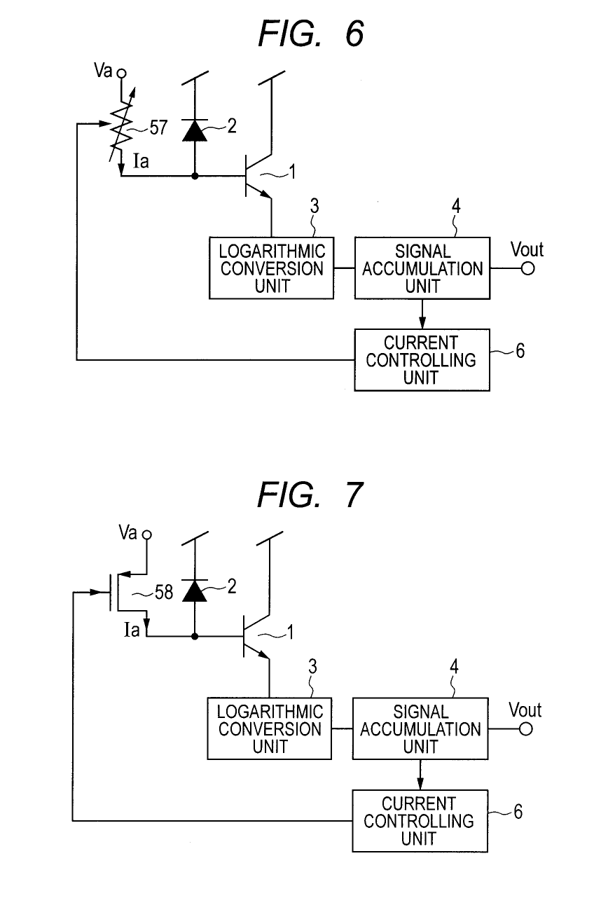

FIG. 6 is a configuration example of a current generating unit 5 according to a third embodiment of the present invention. FIG. 6 illustrates an embodiment describing the current generating unit 5 in FIG. 1 further in detail. The phototransistor 1, the photoelectric conversion element 2, the logarithmic conversion unit 3, the signal accumulation unit 4, and the current controlling unit 6 in FIG. 6 are the same as those in FIG. 1. The current generating unit 5 includes a variable resistor element 57. One end of the variable resistor element 57 is electrically connected to the base of the photoelectric conversion element 2 and the phototransistor 1; and the other end thereof is electrically connected to the node of a constant voltage Va such as the voltage source. The resistor value of the variable resistor element 57 is controlled by the current controlling unit 6, and thereby the current Ia to be added to the base of the phototransistor 1 can be controlled. Thus, in a case in which the photoelectric conversion apparatus includes a plurality of phototransistors, an appropriate output current Ia can be supplied according to the characteristics of each phototransistor. As a result, the pixel-multiplied photoelectric conversion apparatus can obtain good photoelectric conversion characteristics.

### Fourth Embodiment

FIG. 7 is a configuration example of a current generating unit 5 according to a fourth embodiment of the present invention. FIG. 7 illustrates an embodiment describing the current generating unit 5 in FIG. 1 further in detail. The phototransistor 1, the photoelectric conversion element 2, the logarithmic conversion unit 3, the signal accumulation unit 4, and the current controlling unit 6 in FIG. 7 are the same as those in FIG. 1. The current generating unit 5 includes a p-type MOS field-effect transistor 58. The p-type MOS field-effect transistor 58 is configured such that its drain is electrically connected to the node of a constant voltage Va such as the voltage source; its source is electrically connected to the base of the photoelectric conversion element 2 and the phototransistor 1; and its gate is electrically connected to the current controlling unit 6. The current controlling unit 6 can control the current Ia to be added to the base of the phototransistor 1 by controlling the voltage between the gate and the source of the p-type MOS field-effect transistor 58. Thus, in a case in which the photoelectric conversion apparatus includes a plurality of phototransistors, an appropriate output current Ia can be supplied according to the characteristics of each phototransistor. Further, the present embodiment can control a microcurrent in an easier manner than other embodiments having the resistor element illustrated in FIGS. 5 and 6. Furthermore, the present embodiment using the p-type MOS field-effect transistor 58 can reduce the size of the element than the embodiments using the resistor element. As a result, the pixel-multiplied and microminituarized photoelectric conversion apparatus can obtain good photoelectric conversion characteristics.

The above embodiments are merely examples of embodying the present invention and should not be construed to limit the technical scope of the present invention. Specifically, the present invention can be implemented in various forms without departing from the technical idea or the essential characteristics of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-003112, filed Jan. 11, 2011, which is hereby incorporated by reference herein in its entirety.

What is claimed is:

1. A photoelectric conversion apparatus comprising:
a photoelectric conversion element for generating a current by a photoelectric conversion;
a transistor having a base inputted the current generated by the photoelectric conversion element, amplifying the input current and outputting the amplified current from an emitter thereof;
a logarithmic conversion unit for logarithmically converting the current output from the transistor;
a current generating unit for inputting a current to the base of the transistor; and
a current controlling unit for the current output from the current generating unit, based on the signal converted logarithmically by the logarithmic conversion unit under a light shielding state of the photoelectric conversion element.

2. The photoelectric conversion apparatus according to claim 1, wherein
the current generating unit comprising
a signal comparing unit for comparing with a preliminary determined value a signal value of the signal logarithmically converted by the logarithmic conversion unit; and
a control signal generating unit for outputting a control signal for controlling the current generating unit, based on a result of the comparing by the signal comparing unit.

3. The photoelectric conversion apparatus according to claim 1, further comprising
a signal accumulation unit for accumulating the signal logarithmically converted by the logarithmic conversion unit, wherein
the current controlling unit controls the output current from the current generating unit, based on the signal accumulated by the signal accumulation unit under the under the light shielding state of the photoelectric conversion element.

4. The photoelectric conversion apparatus according to claim 3, wherein
the current controlling unit controls the output current from the current generating unit, based on a difference between a signal value accumulated by the signal accumulation unit under the under the light shielding state of the photoelectric conversion element and a signal value under a condition that the current amplification ratio of the transistor has no base current dependency.

5. The photoelectric conversion apparatus according to claim 3, wherein
the current generating unit outputs a current of constant value during a period writing a signal into the signal accumulation unit under a light incident state of the photoelectric conversion element.

6. The photoelectric conversion apparatus according to claim 1, wherein
the current generating unit comprises
a resistor element connected between a voltage node and the base of the transistor,
a voltage source generating a voltage of the voltage node, under a control by the current controlling unit.

7. The photoelectric conversion apparatus according to claim 1, wherein
the current generating unit comprises
a variable resistor element being connected between a constant voltage node and the base of the transistor, and having a resistance value controlled by the current controlling unit.

8. The photoelectric conversion apparatus according to claim 1, wherein
the current generating unit comprises
a field-effect transistor, one of source and drain of the field-effect transistor being connected to a constant voltage node, the other of the field-effect transistor being connected to the base of the transistor, and a gate of the field-effect transistor being connected to the current controlling unit.
